(19) United States
(12) Patent Application Publication
(10) Pub. No.: US 2006/0207688 A1
(43) Pub. Date: Sep. 21, 2006

(54) Method for storing silicon substrate having silicon oxide film formed thereon

(76) Inventors: Akira Kurokawa, Ibaraki (JP); Toshiyuki Fujimoto, Ibaraki (JP); Hidehiko Nonaka, Ibaraki (JP); Shingo Ichimura, Ibaraki (JP)

Correspondence Address: SUGHRUE MION, PLLC, 2100 PENNSYLVANIA AVENUE, N.W., SUITE 800, WASHINGTON, DC, 20037, US

(21) Appl. No.: 11/372,026

(22) Filed: Mar. 10, 2006

(30) Foreign Application Priority Data
Mar. 18, 2005 (JP) 2005-078402

(51) Int. Cl. H01L 21/316

(52) U.S. Cl. 148/33.3; 438/909; 438/787

(57) ABSTRACT

In storing a silicon substrate having a silicon oxide film formed thereon, the present invention provides a means for preventing changes in the silicon oxide film thickness. The present invention relates to a method for storing a silicon substrate having a silicon oxide film formed thereon by immersing the substrate in an aqueous medium contained in a case.

### BACKGROUND OF THE INVENTION

1. Field of the Invention

The present invention relates to a method for storing a silicon substrate having a silicon oxide film formed thereon.

2. Background Art

A silicon oxide film can easily be formed by heating a silicon substrate in an oxidizing atmosphere. Such silicon oxide film is stable, and the thickness thereof does not easily vary at room temperature in a clean air atmosphere. Thus, the thickness of such silicon oxide film can be used as a standard thickness for calibration of thin film thickness measurement equipment. Therefore, in recent years, a silicon substrate having a silicon oxide film formed thereon has been used as a scale for thickness determination.

Silicon oxide films are stable. However, when an adsorptive gas that floats in the air tightly adsorbs to a silicon oxide film, it is difficult to remove the gas from the film in most cases. Some forms of thin film thickness measurement equipment provide measurements in which the thickness of an adsorbed gas layer is added to the thickness of a silicon oxide film. Thus, such adsorbed gas layer mainly causes variations in measurement values. The thickness of an adsorbed gas layer significantly varies depending on the environment in which a sample has been disposed. Therefore, substrates having the same oxide film thickness would be measured as having different thicknesses due to their environments. This problem causes considerable inconvenience in terms of calibration of equipments based on the silicon oxide film thickness of a scale substrate. Although the thickness of such adsorbed gas layer is only several nanometers, it has significant influences particularly when a scale substrate has a nanometer-thickness silicon oxide film.

Heretofore, during transportation and storage of the scale substrate as described above, the substrate has merely been stored in the air for convenience. Therefore, when using such scale substrate, users are required to remove an adsorbed gas layer (contaminated layer) on the substrate surface by washing. However, in some washing methods, there is a risk that a silicon oxide film would be subjected to etching so that the thickness thereof would vary. In addition, it is necessary to select washing methods based on the types of adsorbed substances, resulting in a significant lack of user-friendliness. Further, since selection of washing method is left to users, it is unclear whether or not the silicon oxide film thickness after washing is the same as that upon production and shipment.

As a step in semiconductor manufacturing, in general, a method for storing a sample in a resin case filled with a clean gas has been selected as a method for transporting and storing a clean silicon substrate. However, in such method, a trace amount of a gas (e.g., a gas derived from a binder or a component of the case material) is released from the surface of such resin case, so that adhesion of the gas component to the substrate surface is impossible to avoid. Examples of substances that adhere to a silicon substrate include dioctyl phthalate (DOP), dibutyl phthalate (DBP), triethyl phthalate (TEP), trimethylpentanediol (TMPD), and 2,6-di-tert-butyl-4-methyl-phenol (BHT). These are generated from plastic constituting cases for storing silicon substrates (Takeshi Hattori, “Characterization and Metrology for ULSI Technology” pp. 278-279: 2000 International Conference, edited by D. G. Seiler, A. C. Diebold, T. J. Shaffner, R. McDonald, W. M. Bullis, P. J. Smith, and E. M. Secula). Thus, it cannot be said that a method of storing a substrate in a case is appropriate as a method for transporting and storing a scale substrate.

### SUMMARY OF THE INVENTION

It is an objective of the present invention to provide a means of preventing changes in the thickness of a silicon oxide film during storage of a silicon substrate having such silicon oxide film formed thereon.

As a result of intensive studies, the present inventors have found that a silicon substrate having a silicon oxide film formed thereon may be immersed in an aqueous medium such that adhesion of an adsorptive gas to the silicon oxide film can be prevented. This has led to the completion of the present invention.

That is, the present invention encompasses the following inventions:
(1) A method for storing a silicon substrate having a silicon oxide film formed thereon by immersing the substrate in an aqueous medium in a case;
(2) The method described in (1), wherein the aqueous medium is water;
(3) The method described in (1) or (2), wherein the case is made of an organic polymer material;
(4) The method described in (3), wherein the case is made of fluorocarbon resin;
(5) The method described in (1) or (2), wherein the case is made of silica glass;
(6) The method described in any one of (1) to (5), wherein the case is hermetically sealed;
(7) The method described in any one of (1) to (6), wherein an inert gas is further filled in the case;
(8) The method described in any one of (1) to (6), wherein substantially no gas phase is contained in the case; and
(9) The method described in any one of (1) to (8), wherein, after the production of a silicon substrate having a silicon oxide film formed thereon, steps until the substrate is immersed in the aqueous medium are carried out under an inert gas atmosphere or in vacuo.

According to the method of the present invention, during storage of a silicon substrate having a silicon oxide film formed thereon, changes in the silicon oxide film thickness can be prevented.

### BRIEF DESCRIPTION OF THE DRAWINGS

FIG. 1 shows one embodiment of the present invention.

FIG. 2 shows one embodiment of the present invention.

FIG. 3 shows increases in the silicon oxide film thickness of a substrate that has been stored in a case under a nitrogen atmosphere.

FIG. 4 shows one embodiment of an apparatus for storing the substrate for carrying out the present invention.

### DESCRIPTION OF THE PREFERRED EMBODIMENT

The present invention relates to a method for storing a silicon substrate having a silicon oxide film formed thereon by immersing the substrate in an aqueous medium in a case.

In the present invention, a silicon substrate having a silicon oxide film formed thereon indicates a silicon substrate on which a silicon oxide film is formed. In the present invention, a silicon oxide film includes a silicon dioxide film. In general, such substrate can be formed by heating a silicon substrate under an oxidative atmosphere. In this specification, a silicon substrate having a silicon oxide film formed thereon is also referred to as a substrate with a silicon oxide film. In general, the silicon oxide film thickness of a substrate with a silicon oxide film, which is preferably stored by the method of the present invention, is 1 nm to 10 nm, and preferably 1 nm to 100 nm, but thickness is not particularly limited thereto. In addition, even in the case of a silicon substrate having a nanometer-thickness silicon oxide film, there would be no problem in using as a scale such a substrate stored according to the method of the present invention. In the present invention, a silicon substrate having a silicon oxide film formed thereon involves a substrate having no thin metal film on the surface thereof.

In the present invention, an aqueous medium indicates a liquid medium consisting primarily of water. In general, water contained in the medium accounts for 1% by mass or more, preferably 50% by mass or more, and more preferably 90% by mass or more of the medium. In the present invention, examples of water include ion exchange water, distilled water, pure water, ultrapure water, and degassed ultrapure water.

With the use of water containing the fewest impurities, adhesion of contaminants (metal ions or fine particles) to the silicon oxide film surface can be prevented. In addition, when ultrapure water is used as an aqueous medium, it is easy to remove water from the silicon oxide film surface, such that a clean surface can be obtained, resulting in good user-friendliness.

In the present invention, dissolved oxygen in an aqueous medium, particularly in water, may be reduced. The level of dissolved oxygen is around 8 ppm at room temperature, although it can be reduced to several ppb or less using a deaerator for pure water in which hollow fibers or the like are used. When using a deaerator, the amounts of dissolved nitrogen and carbon dioxide can be reduced, in addition to the amount of dissolved oxygen. The amount of dissolved oxygen can also be reduced with the addition of ammonium sulfite. Therefore, in one embodiment of the present invention, an aqueous solution contains ammonium sulfite. In such case, in general, the amount of ammonium sulfite is 0.01% to 0.1% by mass based on that of the medium; however, it depends on the amount of oxygen dissolved in water. In the present invention, in general, the dissolved oxygen concentration in an aqueous medium is 0.001 ppm to 100 ppm, and preferably 0.1 ppm to 1 ppm.

Water having a reduced amount of dissolved oxygen is used for various applications in semiconductor plants. Thus, the use of the present method can easily be realized as a part of a step in semiconductor manufacturing or at sites of semiconductor plants. In addition, with the use of degassed water, the efficiency of fine particle removal by ultrasonic cleaning is improved, resulting in suppression of contamination on the oxide film surface.

Note that the dissolved oxygen concentration is not particularly necessarily reduced, since the objective of the present invention is not prevention of oxidation of the substrate surface. Therefore, the dissolved oxygen concentrations as described above are sufficient.

Water, particularly ultrapure water having reduced contents of organic substance, may be used as an aqueous medium. Examples of such organic substance include dioctyl phthalate (DOP), dibutyl phthalate (DBP), triethyl phthalate (TEP), trimethylpentanediol (TMPD), and 2,6-di-tert-butyl-4-methyl-phenol (BHT). These become mixed with water when the air in a clean room enters in and exits from a tank for ultrapure water production. Also, these become mixed with water since plastic has been widely used for water pipes. By reducing the amounts of these organic substance, the sedimentation rates of such organic substance on the surface of a silicon substrate that is stored in water can be lowered.

A known example of a method for reducing organic substance content is a method of organic substance degradation with ultraviolet radiation or with the addition of ozone. In particular, a method of ultraviolet radiation as a method for reducing organic substance content is often incorporated into an ultrapure water production system. In addition, to avoid contamination of water with such organic substance, spaces inside a pure water storage tank are filled with nitrogen, such that the air in a clean room would not come into contact with water.

In the present invention, an aqueous medium may comprise a low-molecular-weight alcohol. When ultrapure water becomes contaminated with viable bacteria in the air, the bacteria multiply in the water, resulting in increased organic substance content. However, with the addition of alcohol, the multiplication of viable bacteria can be inhibited, and the oxide film surface remains hydrophilic.

Examples of lower alcohol include alcohol having one to five carbon atoms such as methanol, ethanol, isopropyl alcohol, butanol, pentyl alcohol, and allylalcohol. In general, the amount of alcohol is 10% to 99% by mass, preferably 1% to 10% by mass, and more preferably 0.01% to 1% by mass.

In the present invention, an aqueous medium may be ultrapure water in which gas, for example one or more gases selected from hydrogen, nitrogen, and argon, has been dissolved, which is used in a step of semiconductor manufacturing because of its fine particle removal effect.

Such water is used for various applications in semiconductor plants. Thus, the use of the present method can easily be realized as a part of a step of semiconductor manufacturing or at sites of semiconductor plants. In particular, water in which hydrogen has been dissolved is effective for removing fine particles that have adhered to the substrate surface. It has been reported that it is possible to remove 95% or more of the alumina particles due to intended contamination within a minute using water in which 1 ppm or more of hydrogen has been dissolved (e.g., “Wet Science ga Hiraku Product Innovation (Product Innovation Pioneered by Wet Science):” edited by Tadahiro Ohmi, published by Sipec Corp. (Realize Advanced Technology Limited)).

In the present invention, an aqueous medium is preferably water, and particularly preferably ultrapure water.

In the present invention, a case that can be used for storing a substrate is a case generally used in the field. Examples thereof are cases made of an inorganic or organic material. Examples of an inorganic material include glass, silica glass, fused silica, synthetic quartz, alumina, sapphire, ceramics, forsterite, and photosensitive glass. Examples of an organic material include polymer materials.

Preferably, in the present invention, the case used is made of a polymer material. Such polymer material may adequately be selected from those having properties suitable for the purpose of the present invention. Either synthetic or naturally occurring polymer material may be used. A combination of two or more materials may also be used. Specifically, examples of such materials include fluorocarbon resins such as polytetrafluoroethylene (PTFE), ethylene tetrafluoride-perfluoroalkyl vinyl ether copolymers (PFA), tetrafluoroethylene-hexafluoropropylene copolymers (4.6 fluoride, EFP), tetrafluoroethylene-ethylene copolymers (ETFE), polyvinylidene fluoride (2 fluoride, PVDF), and polychlorotrifluoroethylene (3 fluoride, PCTFE); polyolefins such as polypropylene, polyethylene, polybutene, polystyrene, polyvinyl chloride, polyvinyl alcohol, and polyvinyl acetate; polyamides such as nylons (nylon 6, nylon 66, nylon 11, nylon 12, nylon MXD6, and the like); polyesters such as polybutylene terephthalate, polyethylene terephthalate, and polytrimethylene terephthalate; polycarbonate; polyurethane; polylactic acid; acrylonitrile butadiene styrene resin (ABS resin); acrylic resin; methylpentene resin; phenol resin; melamine resin; epoxy resin; cellulose; cellulose acetate; chitin; cotton; and silk.

Preferably, in the present invention, such case is made of fluorocarbon resin, and is particularly preferably made of polytetrafluoroethylene, tetrafluoroethylene-perfluoroalkyl vinyl ether copolymers, or silica glass.

A person skilled in the art can adequately design the shape of the case in accordance with the shape of a substrate with a silicon oxide film. Examples of such case are not limited as long as the case can accommodate a substrate with a silicon oxide film. However, the case should be sufficient in terms of being able to be filled with a liquid without experiencing leakage, and in that one or more substrates can be accommodated therein such that the substrates can be immersed in the liquid. In one embodiment of the present invention, the case is composed of a box member, in which a substrate with a silicon oxide film is disposed, and a cover member, which fits on the box member. In addition, the case has an inlet for introducing an aqueous medium, preferably in the cover member. Preferably, in the present invention, the case is hermetically sealed. Such case indicates a case capable of being hermetically sealed whereby no gas or liquid leaks from the inside thereof or enters from the outside thereof during storage of a substrate with a silicon oxide film.

In one embodiment of the present invention, a case containing a substrate with a silicon oxide film is filled with an aqueous solution such that no gas phase is substantially contained therein. The condition of no gas phase being substantially contained in a case indicates that the cubic volume of the gas phase is 5% or less based on the volume of the case. In another embodiment of the present invention, a case containing a substrate with a silicon oxide film is filled with an inert gas, in addition to an aqueous medium. Examples of such inert gas include helium, argon, nitrogen, and hydrogen. The volume of the inert gas filled is not particularly limited unless a silicon oxide film on the substrate is exposed from the aqueous medium. As a result of filling a case with an inert gas, there is no possibility that a liquid inside the case would come into contact with air containing contaminants. Thus, contamination of the surface of a substrate with a silicon oxide film can be suppressed. In addition, in embodiments of the present invention, it is only required that a series of steps of transferring a substrate to a case, of filling the case with ultrapure water, and of securing a cover member be carried out in an inert gas atmosphere such as a high purity nitrogen gas atmosphere. Therefore, such steps can easily be realized.

Either the introduction of a substrate with a silicon oxide film into a case or the introduction of an aqueous medium into a case may be conducted first. Preferably, the introduction of a substrate with a silicon oxide film is conducted first.

In the present invention, a substrate with a silicon oxide film is immersed in an aqueous medium such that at least the silicon oxide film side of the substrate becomes covered with the medium. Preferably, the entire substrate with a silicon oxide film is immersed in the aqueous medium.

In the present invention, a case may previously be washed prior to introducing an aqueous medium and a substrate with a silicon oxide film thereinto. A washing method generally used in the field may be used, depending on types of case materials. Such washing method can be carried out by cleaning in an organic solvents such as acetone, isopropyl alcohol, or methanol; an inorganic acid such as hydrochloric acid or nitric acid; water; ozone-containing water; a surfactant such as phosphorus free neutral wash; or ultrasonic cleaning in the above liquid. The case is previously washed such that contamination of the silicon oxide film surface can be prevented.

In one embodiment of the present invention, after the production of a silicon substrate having a silicon oxide film formed thereon, steps until such substrate is immersed in an aqueous medium are carried out under a high purity nitrogen atmosphere, under an inert gas atmosphere or in vacuo.

The condition of a high purity nitrogen atmosphere indicates a condition in which the nitrogen concentration is generally 99.999% or more, and preferably, in which the residual oxygen partial pressure in the atmosphere is 1 ppm or less. As to an inert gas, it is already described.

That is, after the production of a silicon substrate having a silicon oxide film formed thereon, the introduction of the substrate into a case and the introduction of an aqueous medium into a case are carried out under conditions where an adsorptive gas does not exist or an adsorptive gas exists at a low concentration. Thus, the silicon oxide film does not come into contact with an adsorptive gas before the substrate becomes immersed in the aqueous medium.

In the present invention, an adsorptive gas indicates a gas that adheres to the silicon oxide film surface, resulting in changes in measurement values of the film thickness. Examples of such gas include a gas released from the wall surface of a case, a gas released from plastic such as dioctyl phthalate (DOP), dibutyl phthalate (DBP), triethyl phthalate (TEP), trimethylpentanediol (TMPD), or 2,6-di-tert-butyl-4-methyl-phenol (BHT), and a gas that exists in a clean room.

Preferably, after the production of a silicon oxide film, steps until a substrate with a silicon oxide film is immersed in an aqueous medium are carried out under conditions where the film is shielded from the air. Thus, the silicon oxide film surface is not contaminated due to adhesion of contaminants in the air thereto.

With the method of the present invention, it is possible to suppress dissolution of a gas that has been released from the wall surface of a case into the aqueous medium introduced, or to suppress the release of such gas from the wall surface. Thus, the amount of the gas released that adsorbs to the silicon oxide film surface can significantly be reduced. Therefore, contamination of the silicon oxide film surface can also be prevented.

According to the present invention, it is possible to store a silicon substrate having a silicon oxide film formed thereon without causing changes in the film thickness thereof for a long period of time such as 500 hours or more, and preferably 1000 hours or more. Thus, in terms of applications wherein such silicon oxide film thickness is used as a scale, the reliability of the film as a scale can be improved. In addition, since a substrate with a silicon oxide film that has been stored in accordance with the method of the present invention is not contaminated, there is no necessity to wash it before use, resulting in good user-friendliness.

A substrate with a silicon oxide film that has been stored in accordance with the method of the present invention can be used as a standard scale for ellipsometry, spectral ellipsometry, X-ray photoelectron spectroscopy (XPS), Auger electron spectroscopy (AES), Rutherford backscattering spectroscopy (RBS), medium energy ion scattering spectroscopy (MEIS), X-ray reflectometry (XRR), electron-excited X-ray appearance potential spectroscopy, and the like.

The present invention will be hereafter described in greater detail with reference to the following examples, although the technical scope of the present invention is not limited thereto.

The present description includes part or all of the contents as disclosed in the description and/or drawing of Japanese Patent Application No. 2005-78402, which is a priority document of the present application.

### EXAMPLES

### Example 1

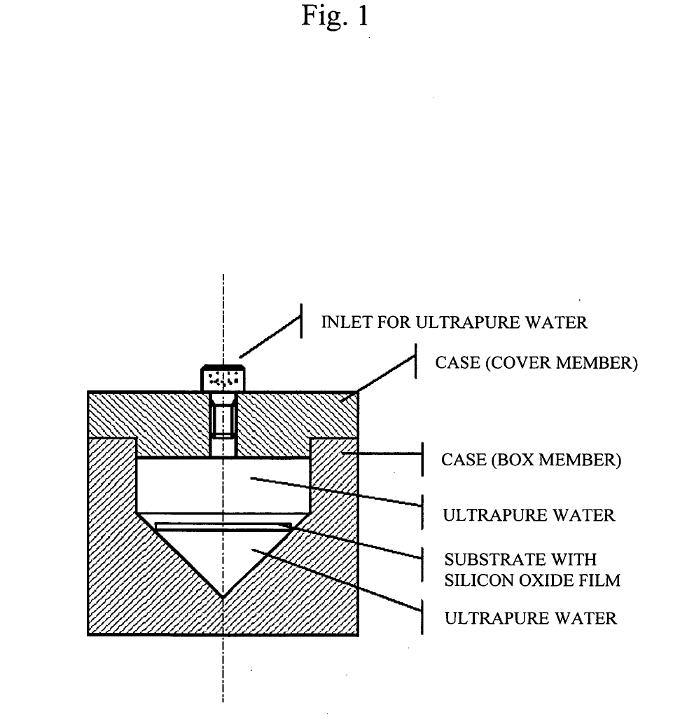

FIG. 1 shows one embodiment of the present invention. A substrate with a silicon oxide film was stored in a hermetically sealed case that was composed of a box member and a cover member, which were made of polytetrafluoroethylene resin. The case was filled with ultrapure water that was introduced from an inlet provided on the cover member, which was the upper part of the case. In this embodiment, the case is filled with ultrapure water, such that no gas phase is substantially contained in the case. Thereafter, the inlet was closed with a screw made of polytetrafluoroethylene resin, such that the case was hermetically sealed. As a result, the substrate was shielded from the outside air, and thus the surface of the substrate with a silicon oxide film did not become contaminated, resulting in no change in the silicon oxide film thickness.

### Example 2

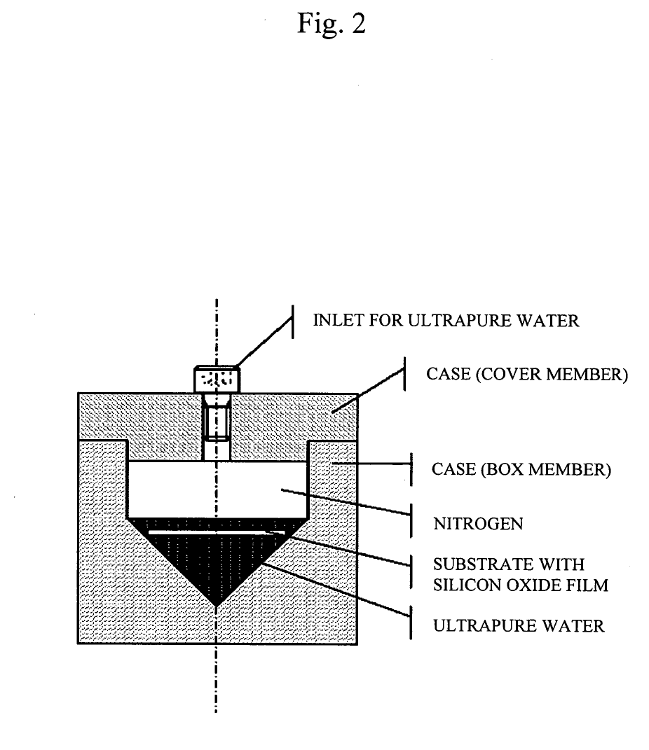

FIG. 2 shows one embodiment of the present invention. A substrate with a silicon oxide film was stored in a hermetically sealed case that was composed of a box member and a cover member, which were made of polytetrafluoroethylene resin. The case was filled with ultrapure water that was introduced from an inlet provided on the cover member, which was the upper part of the case. In this embodiment, the gas phase in the case consists of nitrogen. Also in this embodiment, a substrate with a silicon oxide film is immersed in ultrapure water, such that the substrate is protected from contamination, resulting in no change in the silicon oxide film thickness.

### Example 3

Two substrates, each with a silicon oxide film, were manufactured. The thickness of the silicon oxide film of each substrate was determined to be 9 nm using an optical ellipsometer.

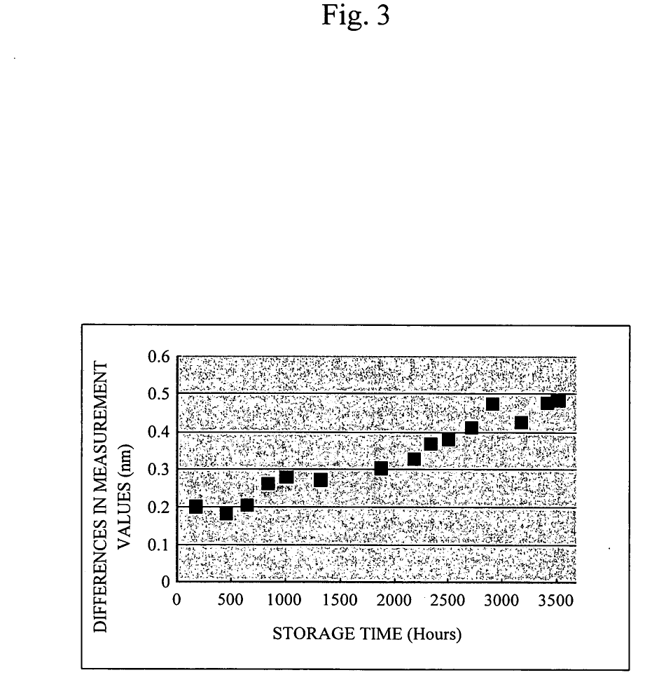

One of the above substrates was stored in a case made of polytetrafluoroethylene resin that was filled with nitrogen. Then, the substrate was continually removed from the case for the determination of the silicon oxide film thickness using an optical ellipsometer. FIG. 3 shows increases in the film thickness. These increases are thought to have resulted from contamination caused by adsorption of a gas, which was released from the wall surface of the case, to the surface of the silicon oxide film.

A case made of polytetrafluoroethylene resin was filled with ultrapure water, and the other substrate described above was immersed and stored therein. The dissolved oxygen concentration in the ultrapure water was determined to be 7 ppm. There was no change in the silicon oxide film thickness of the substrate, which had been immersed in the ultrapure water, and the thickness remained 9 nm even after 3500 hours.

As described above, it was shown that the silicon oxide film thickness of the substrate gradually increased when the substrate had been stored under a nitrogen atmosphere, while on the contrary, there was no change in the silicon oxide film thickness of the substrate that had been stored in accordance with the method of the present invention.

In addition, according to the method of the present invention, there was no change in the silicon oxide film thickness under the same conditions when the film thickness was 3 nm and 5 nm.

### Example 4

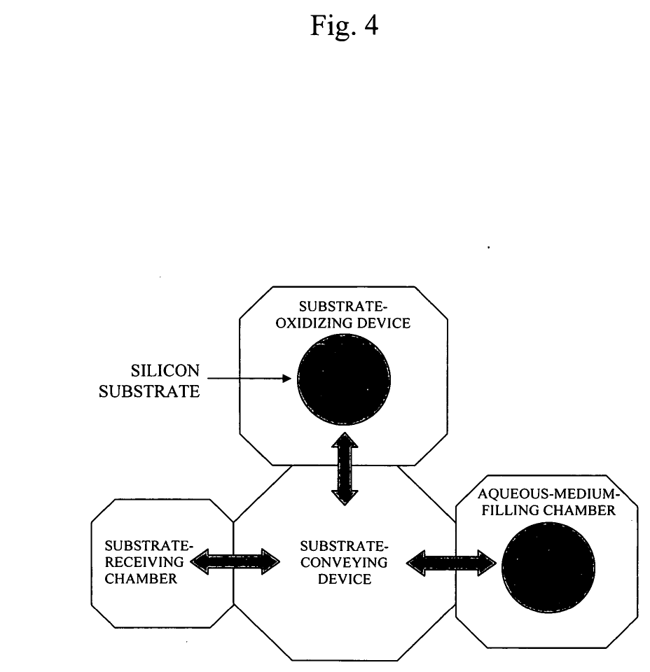

FIG. 4 shows a schematic diagram of an apparatus for storing a substrate in one embodiment for carrying out the present invention. The apparatus of this embodiment comprises a substrate-receiving chamber, a substrate-oxidizing device, a substrate-conveying device, and an aqueous-medium-filling chamber. After a silicon substrate is introduced in a substrate-receiving chamber, it is transferred to a substrate-oxidizing device via a substrate-conveying device. The silicon substrate is oxidized in the substrate-oxidizing device such that a silicon oxide film is formed on the silicon substrate. The thus produced substrate with a silicon oxide film is removed from the substrate-oxidizing device and transferred into the aqueous-medium-filling chamber, where the substrate with a silicon oxide film is stored in a case and an aqueous medium is introduced into the case. Then, the case that contains the substrate with a silicon oxide film that has been immersed in the aqueous medium is transferred out of the apparatus.

Here, the insides of the substrate-receiving chamber, the substrate-oxidizing device, the substrate-conveying device, and the aqueous-medium-filling chamber are shielded from the air. Preferably, the insides are filled with an inert gas. Thus, a silicon substrate or a substrate with a silicon oxide film does not come into contact with the outside air, so that there would be no increase in the oxide film thickness in the apparatus.

Here, the case for storing a substrate was made of synthetic quartz or polytetrafluoroethylene resin for a substrate 50 mm in diameter, or of polytetrafluoroethylene resin or ethylene tetrafluoride-perfluoroalkyl vinyl ether copolymer (PFA) for a substrate 200 mm in diameter.

All publications, patents, and patent applications cited herein are incorporated herein by reference in their entirety.

What is claimed is:

1. A method for storing a silicon substrate having a silicon oxide film formed thereon by immersing the substrate in an aqueous medium in a case.

2. The method according to claim 1, wherein the aqueous medium is water.

3. The method according to claim 1, wherein the case is made of an organic polymer material.

4. The method according to claim 2, wherein the case is made of an organic polymer material.

5. The method according to claim 3, wherein the case is made of fluorocarbon resin.

6. The method according to claim 4, wherein the case is made of fluorocarbon resin.

7. The method according to claim 1, wherein the case is made of silica glass.

8. The method according to claim 2, wherein the case is made of silica glass.

9. The method according to claim 1, wherein the case is hermetically sealed.

10. The method according to claim 9, wherein an inert gas is further filled in the inside of the case.

11. The method according to claim 9, wherein substantially no gas phase is contained in the case.

12. The method according to claim 1, wherein, after the production of a silicon substrate having a silicon oxide film formed thereon, steps until the substrate is immersed in the aqueous medium are carried out under an inert gas atmosphere or in vacuo.
